(19) United States
(12) Patent Application Publication
(10) Pub. No.: US 2025/0081471 A1
(43) Pub. Date: Mar. 6, 2025

(54) SEMICONDUCTOR DEVICE AND METHOD OF MANUFACTURING SEMICONDUCTOR DEVICE

(71) Applicant: SK hynix Inc., Icheon-si (KR)

(72) Inventor: Jae Hyuk PARK, Icheon (KR)

(21) Appl. No.: 18/543,694

(22) Filed: Dec. 18, 2023

(30) Foreign Application Priority Data
Sep. 1, 2023 (KR) 10-2023-0116007

(51) Int. Cl. H10B 63/10; H10B 63/00; H10N 70/00; H10N 70/20

(52) U.S. Cl. CPC H10B 63/10; H10B 63/845; H10N 70/011; H10N 70/231; H10N 70/8616

(57) ABSTRACT

A semiconductor device may include a first electrode, a second electrode, a variable resistance layer positioned between the first electrode and the second electrode and maintaining a phase before and after a program operation, a non-conductive sealing layer positioned between the first electrode and the variable resistance layer, and a nanostructure positioned inside the non-conductive sealing layer and spaced apart from the variable resistance layer.

### CROSS-REFERENCE TO RELATED APPLICATION

This application claims priority under 35 U.S.C. § 119 to Korean Patent Application No. 10-2023-0116007 filed on Sep. 1, 2023, which is incorporated herein by reference in its entirety.

### BACKGROUND

### 1. Technical Field

The present disclosure relates to an electronic device, and more particularly, to a semiconductor device and a method of manufacturing the semiconductor device.

### 2. Related Art

Recently, with the miniaturization, lower power consumption, higher performance, and diversification of an electronic device, a semiconductor device capable of storing information in various electronic devices such as a computer and a portable communication device is being desirable. Therefore, research is being conducted on a semiconductor device capable of storing data using a characteristic of switching between different resistance states according to an applied voltage or current. The semiconductor device may include a resistive random access memory (RRAM), a phase-change random access memory (PRAM), a ferroelectric random access memory (FRAM), a magnetic random access memory (MRAM), an E-fuse, and the like.

### SUMMARY

According to an embodiment of the present disclosure, a semiconductor device may include a first electrode, a second electrode, a variable resistance layer positioned between the first electrode and the second electrode and maintaining a phase before and after a program operation, a non-conductive sealing layer positioned between the first electrode and the variable resistance layer, and a nanostructure positioned inside the non-conductive sealing layer and spaced apart from the variable resistance layer.

According to an embodiment of the present disclosure, a semiconductor device may include a first electrode, a second electrode, a variable resistance layer positioned between the first electrode and the second electrode and maintaining a phase before and after a program operation, a nanodot positioned on a surface of the first electrode, and a non-conductive sealing layer surrounding the nanodot and filling between the first electrode and the variable resistance layer and between the nanodot and the variable resistance layer.

According to an embodiment of the present disclosure, a method of manufacturing a semiconductor device may include forming a first electrode, forming a nanostructure on the first electrode, forming a non-conductive sealing layer on the first electrode to surround the nanostructure, forming a variable resistance layer on the non-conductive sealing layer, and forming a second electrode on the variable resistance layer.

### BRIEF DESCRIPTION OF THE DRAWINGS

FIG. 1 is a diagram illustrating a structure of a semiconductor device according to an embodiment of the present disclosure.

FIG. 2 is a diagram illustrating a structure of a semiconductor device according to an embodiment of the present disclosure.

FIG. 3 is a diagram illustrating a structure of a semiconductor device according to an embodiment of the present disclosure.

FIGS. 4A and 4B are diagrams each illustrating a structure of a semiconductor device according to an embodiment of the present disclosure.

FIGS. 5A and 5B are diagrams each illustrating an operation of a semiconductor device according to an embodiment of the present disclosure.

FIGS. 6A, 6B, and 6C are cross-sectional views illustrating a method of manufacturing a semiconductor device according to an embodiment of the present disclosure.

FIGS. 7A, 7B, 7C, and 7D are diagrams illustrating a method of manufacturing a semiconductor device according to an embodiment of the present disclosure.

### DETAILED DESCRIPTION

An embodiment of the present disclosure provides a semiconductor device and a method of manufacturing the semiconductor device having a stable structure and improved characteristic.

An integration degree of a semiconductor device may be improved by stacking memory cells in a three dimension. In addition, a semiconductor device having a stable structure and improved reliability may be provided.

As used herein, “at least one of . . . and” indicates a disjunctive list of each of items as well as possible combination(s). For example, “at least one of A and B” indicates “only A, or only B, or both A and B,” and “at least one of A, B, and C” indicates “only A, or only B, only C, or both A and B, or both A and C, or both B and C, or all of A and B and C,” and so on. Hereinafter, embodiments according to the technical spirit of the present disclosure are described with reference to the accompanying drawings.

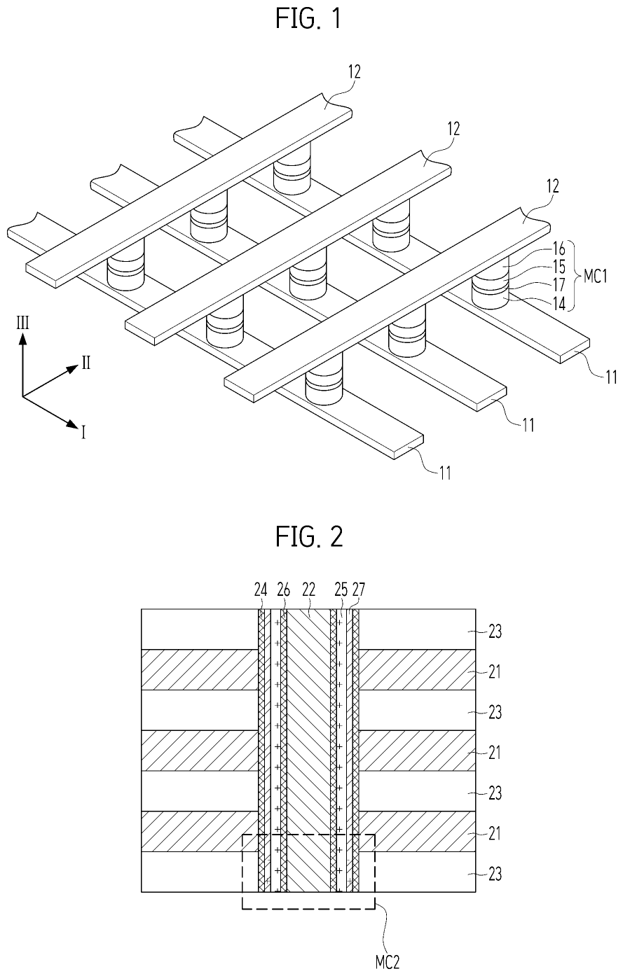

FIG. 1 is a diagram illustrating a structure of a semiconductor device according to an embodiment of the present disclosure.

Referring to FIG. 1, the semiconductor device according to an embodiment of the present disclosure may include at least one first access line 11, at least one second access line 12, or at least one first memory cell MC1, or may include a combination thereof.

The first access line 11 may extend in a first direction I. The second access line 12 may extend in a second direction II crossing the first direction I. The first access line 11 and the second access line 12 may be stacked in a third direction III. The third direction III may be a direction orthogonal to a plane defined by the first direction I and the second direction II. The first access line 11 and the second access line 12 may be a word line or a bit line. As an embodiment, the first access line 11 may be the word line and the second access line 12 may be the bit line. Alternatively, the first access line 11 may be the bit line and the second access line 12 may be the word line.

The first memory cell MC1 may be positioned in a region where the first access line 11 and the second access line 12 cross. The first memory cells MC1 may be arranged in the first direction I and the second direction II. The first memory cell MC1 may be connected between the first access line 11 and the second access line 12.

The first memory cell MC1 may include at least one of a first electrode 14, a second electrode 16, a variable resistance layer 15, and a sealing layer 17. The variable resistance layer 15 may be positioned between the first electrode 14 and the second electrode 16. The first electrode 14 may be electrically connected to the first access line 11. The second electrode 16 may be electrically connected to the second access line 12. For reference, the first memory cell MC1 may include a switching layer instead of the variable resistance layer 15, or may further include a switching layer in addition to the variable resistance layer 15.

The sealing layer 17 may include a nanostructure therein, and may seal the nanostructure so that the nanostructure does not contact the variable resistance layer 15. The sealing layer 17 may be positioned in a first region between the first electrode 14 and the variable resistance layer 15, or a second region between the second electrode 16 and the variable resistance layer 15. In some embodiments, the sealing layer 17 and an additional sealing layer (not shown) having a similar configuration to the sealing layer 17 and including the same materials as the sealing layer 17 may be positioned in the first region and the second region, respectively. As an embodiment, the first electrode 14, the sealing layer 17, the variable resistance layer 15, and the second electrode 16 may be stacked in the third direction III. In this case, the nanostructure may be in contact with the first electrode 14 and may be used as an electrode together with the first electrode 14. Specifically, the nanostructure (e.g., nanodots) may have an electrical conductivity sufficiently high to function as a single integrated electrode together with the first electrode 14. As an embodiment, the first electrode 14, the variable resistance layer 15, the sealing layer 17, and the second electrode 16 may be stacked in the third direction III. In this case, the nanostructure may be in contact with the second electrode 16 and may be used as an electrode together with the second electrode 16.

In addition, although not shown in the present drawing, the semiconductor device may further include circuits for controlling the first access lines 11 and the second access lines 12. As an embodiment, the semiconductor device may include a first circuit such as a word line decoder or a word line driver. The first circuit may select the first access line on which a program operation is to be performed according to a row address. The semiconductor device may include a second circuit such as a bit line decoder and a bit line driver. The second circuit may select the second access line on which the program operation is to be performed according to a column address. During the program operation, the first memory cell MC1 connected between the selected first access line 11 and the selected second access line 12 may be selected.

According to the structure described above, the first memory cell MC1 may include the sealing layer 17, and the nanostructure may be positioned within the sealing layer 17. The effective areas of the first electrode 14 and the second electrode 16 may be different according to the nanostructure, and the first memory cell MC1 may have an asymmetric electrode structure. Therefore, a program window may be increased and a program speed may be increased.

FIG. 2 is a diagram illustrating a structure of a semiconductor device according to an embodiment of the present disclosure. Hereinafter, contents overlapping the contents described above may be omitted for the interest of brevity.

Referring to FIG. 2, the semiconductor device may include at least one of at least one first access line 21, at least one second access line 22, at least one second memory cell MC2, and at least one insulating layer 23.

The first access lines 21 may be stacked alternately with the insulating layers 23. The second access line 22 may pass through the first access lines 21. As an embodiment, the second access line 22 may extend in a vertical direction through the first access lines 21 and the insulating layers 23. The second access line 22 may have a pillar shape, and may have a cross-section of a circle, an ellipse, a polygon, or the like in a plane. The first access line 21 and the second access line 22 may be a word line or a bit line. As an embodiment, the first access line 21 may be the word line and the second access line 22 may be the bit line. Alternatively, the first access line 21 may be the bit line and the second access line 22 may be the word line.

The second memory cell MC2 may be connected between the first access line 21 and the second access line 22. The second memory cell MC2 may be positioned in a region where the first access line 21 and the second access line 22 cross. The second memory cells MC2 may be stacked along the second access line 22. The stacked second memory cells MC2 may share the second access line 22, a first electrode 24, a second electrode 26, a variable resistance layer 25, and a sealing layer 27.

The second memory cell MC2 may include at least one of the first electrode 24, the second electrode 26, the variable resistance layer 25, and the sealing layer 27. The first electrode 24, the variable resistance layer 25, the second electrode 26, and the sealing layer 27 may surround a sidewall of the second access line 22. The variable resistance layer 25 may be positioned between the first electrode 24 and the second electrode 26. The sealing layer 27 may include a nanostructure. The sealing layer 27 may be positioned in a first region between the first electrode 24 and the variable resistance layer 25, or may be positioned in a second region between the second electrode 26 and the variable resistance layer 25. In some embodiments, the sealing layer 27 and an additional sealing layer (not shown) having a similar configuration to the sealing layer 27 and including the same materials as the sealing layer 27 may be positioned in the first region and the second region, respectively.

According to the structure described above, the second memory cell MC2 may include the sealing layer 27, and a nanostructure may be positioned inside the sealing layer 27. The second memory cell MC2 may have an asymmetric electrode structure caused by the nanostructure. Therefore, the program window may be increased and the program speed may be increased.

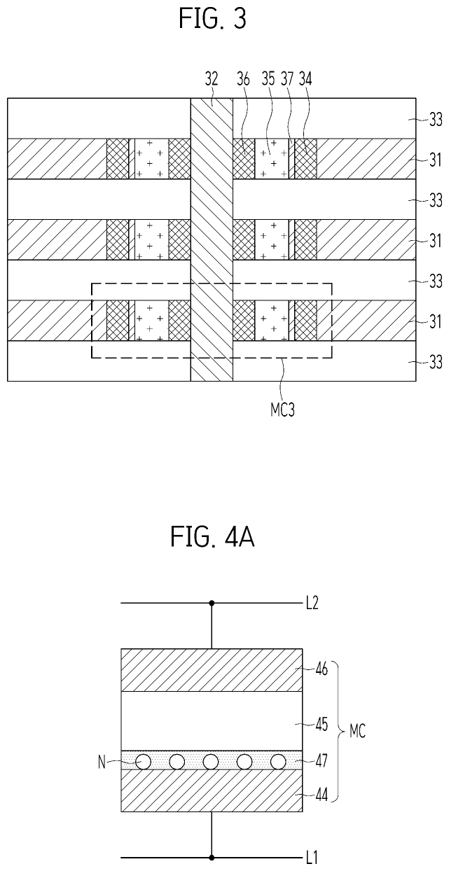

FIG. 3 is a diagram illustrating a structure of a semiconductor device according to an embodiment of the present disclosure. Hereinafter, contents overlapping those described above may be omitted for the interest of brevity.

Referring to FIG. 3, the semiconductor device may include at least one of at least one first access line 31, at least one second access line 32, at least one third memory cell MC3, and at least one insulating layer 33.

The first access lines 31 may be stacked alternately with the insulating layers 33. The second access line 32 may pass through the first access lines 31. As an embodiment, the second access line 32 may extend in the vertical direction through the first access lines 31 and the insulating layers 33. The second access line 32 may have a pillar shape, and may have a cross-section of a circle, an ellipse, a polygon, or the like in a plane. The first access line 31 and the second access line 32 may be a word line or a bit line. As an embodiment, the first access line 31 may be the word line and the second access line 32 may be the bit line. Alternatively, the first access line 31 may be the bit line and the second access line 32 may be the word line.

The third memory cell MC3 may be connected between the first access line 31 and the second access line 32. The third memory cell MC3 may be positioned in a region where the first access line 31 and the second access line 32 cross. The third memory cells MC3 may be stacked along the second access line 32, and the stacked third memory cells MC3 may share the second access line 32.

The third memory cell MC3 may include at least one of a first electrode 34, a second electrode 36, a variable resistance layer 35, and a sealing layer 37. The first electrode 34, the variable resistance layer 35, the second electrode 36, and the sealing layer 37 may partially surround a sidewall of the second access line 32. The first electrode 34, the second electrode 36, the variable resistance layer 35, and the sealing layer 37 may have a ring shape and may be positioned between the stacked insulating layers 33. The variable resistance layer 35 may be positioned between the first electrode 34 and the second electrode 36. The sealing layer 37 may include a nanostructure. The sealing layer 37 may be positioned in a first region between the first electrode 34 and the variable resistance layer 35, or may be positioned in a second region between the second electrode 36 and the variable resistance layer 35. In some embodiments, the sealing layer 37 and an additional sealing layer (not shown) having a similar configuration to the sealing layer 37 and including the same materials as the sealing layer 37 may be positioned in the first region and the second region, respectively.

According to the structure described above, the third memory cell MC3 may include the sealing layer 37, and the nanostructure may be positioned inside the sealing layer 37. The third memory cell MC3 may have an asymmetric electrode structure caused by the nanostructure. Therefore, the program window may be increased and the program speed may be increased.

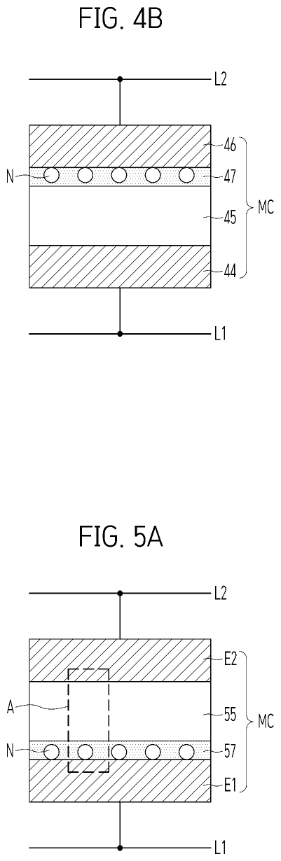

FIGS. 4A and 4B are diagrams each illustrating a structure of a semiconductor device according to an embodiment of the present disclosure. Hereinafter, contents overlapping the contents described above may be omitted for the interest of brevity.

Referring to FIG. 4A, the semiconductor device may include a first access line L1, a second access line L2, and a memory cell MC. The memory cell MC may be connected between the first access line L1 and the second access line L2. The memory cell MC may include a first electrode 44, a variable resistance layer 45, a second electrode 46, a sealing layer 47, and a nanostructure N.

The variable resistance layer 45 may be positioned between the first electrode 44 and the second electrode 46. The variable resistance layer 45 may have a characteristic of reversibly transitioning between different resistance states according to a voltage or a current applied to the memory cell MC. As an embodiment, when the variable resistance layer 45 has a low resistance state, data having a first value (e.g., a logic high level ‘1’) may be stored, and when the variable resistance layer 45 has a high resistance state, data having a second value (e.g., a logic low level ‘0’) may be stored.

As an embodiment, the variable resistance layer 45 may include a resistive material. Data may be stored by generating or disappearing an electrical path within the variable resistance layer 45. As an embodiment, the variable resistance layer 45 may include a transition metal oxide or a metal oxide such as a perovskite-based material.

As an embodiment, the variable resistance layer 45 may have an MTJ structure including a magnetization pinned layer, a tunnel barrier layer, and a magnetization free layer. Data may be stored according to a change in a magnetization direction of the magnetization free layer with respect to a magnetization direction of the magnetization pinned layer. As an embodiment, the magnetization pinned layer and the magnetization free layer may include a magnetic material, and the tunnel barrier layer may include a metal oxide.

As an embodiment, the variable resistance layer 45 may include a phase change material or may include a chalcogenide-based material. The variable resistance layer 45 may change a phase according to a program operation. As an embodiment, the variable resistance layer 45 may have a crystalline state of a low resistance by a set operation. As an embodiment, the variable resistance layer 45 may have an amorphous state of a high resistance by a reset operation. Therefore, data may be stored in the memory cell by using a resistance difference according to the phase of the variable resistance layer 45.

As an embodiment, the variable resistance layer 45 may include a variable resistance material of which a resistance changes without a phase change. For example, the variable resistance layer 45 may include a chalcogenide-based material. The variable resistance layer 45 may function as a memory element and a selection element simultaneously. The variable resistance layer 45 may maintain an image before and after the program operation. As an embodiment, the variable resistance layer 45 may have an amorphous state and may maintain the amorphous state without changing to a crystalline state after the program operation. According to a program voltage applied to the memory cell, an element in the chalcogenide material may migrate and a composition of the chalcogenide material may change. Accordingly, a threshold voltage of the memory cell may be changed, and the memory cell may be programmed into at least two states. As an embodiment, the memory cell may be programmed to a set state or reset state using the program voltage of different polarities. Therefore, data may be stored in the memory cell by using a threshold voltage difference of the memory cells. For reference, the memory cell MC may additionally include a selection element.

The sealing layer 47 may be positioned between the first electrode 44 and the variable resistance layer 45. The nanostructure N may be positioned inside the sealing layer 47. The nanostructure N may include a structure having a size of several nanometers (nm), such as a nanodot, a nano rod, a nano wire, a nano tube, or a nano sheet. The nanostructure N may be positioned on a surface of the first electrode 44. The nanostructure N may include a conductive material. As an embodiment, the nanostructure N may include at least one of nickel (Ni), silver (Ag), platinum (Pt), gold (Au), copper (Cu), and aluminum (Al). The nanostructure N may be in contact with the first electrode 44 and may be electrically connected to the first electrode 44. The nanostructure N may be used as an electrode together with the first electrode 44.

The sealing layer 47 may surround the nanostructure N and fill between the first electrode 44 and the variable resistance layer 45 and between the nanostructure N and the variable resistance layer 45. The nanostructure N and the variable resistance layer 45 may be separated by the sealing layer 47. In other words, the nanostructure N may be embedded in the sealing layer 47 such that the nanostructure N contacts the first electrode 44 and is spaced apart from the variable resistance layer 45. The sealing layer 47 may include a non-conductive material. As an embodiment, the sealing layer 47 may include at least one of oxide, nitride, and carbon.

A thermal conductivity of the sealing layer 47 may be related to heat loss occurring during the program operation. During the program operation, when a bias is applied to the first electrode 44 and the second electrode 46 and a current flows through the memory cell MC, Joule heating may occur. When the program operation is performed using a change in the composition of the chalcogenide material, a speed of an element movement may be increased and a program speed may be increased by reducing heat loss.

When the sealing layer 47 has a relatively high thermal conductivity such as aluminum oxide Al₂O₃, heat generated during the program operation may be lost to the surroundings. In this case, a resistance change of the variable resistance layer 45 may slow down, and the speed of the program operation may be decreased. Therefore, the sealing layer 47 may include a material having a relatively low thermal conductivity to reduce heat loss during the program operation. Specifically, when the sealing layer 47 includes a material having a relatively low thermal conductivity, the sealing layer 47 provides a relatively high thermal resistance to reduce heat loss to the surroundings during a program operation, thereby leading to a relatively high temperature in the variable resistance layer 45. Such a relatively high temperature may assist ionic migration of one or more elements in the variable resistance layer 45 to increase a speed of the program operation. For example, the sealing layer 47 may include a material having a thermal conductivity less than 20 W/mK. As an embodiment, the sealing layer 47 may include an oxide and may include at least one of FexOy, SiOx, and TiOx. The sealing layer 47 may include non-oxide and may include at least one of BNx, graphene, and SiNx.

For reference, when a program operation is performed using the phase change of the chalcogenide material, a set operation including a melting process may be improved by reducing heat loss, but a reset operation including a quenching process may be deteriorated due to the reduced heat loss. Therefore, a sealing material may be determined in consideration of a material of the variable resistance layer 45, an operation principle of the memory cell, a dielectric constant, and the like.

The sealing layer 47 may be a diffusion barrier layer. The sealing layer 47 may significantly reduce a material movement between the first electrode 44, the variable resistance layer 45, and the second electrode 46. Diffusion of a metal included in the first electrode 44 and the second electrode 46 to the variable resistance layer 45 may be reduced, and diffusion of an element of the variable resistance layer 45 to the first electrode 44 or the second electrode 46 may be reduced. Accordingly, reliability may be improved.

The first electrode 44 may be electrically connected to the first access line L1, and the second electrode 46 may be electrically connected to the second access line L2. The first electrode 44 and the second electrode 46 may include a conductive material such as polysilicon or metal. As an embodiment, the first electrode 44 and the second electrode 46 may include polysilicon, tungsten (W), tungsten nitride (WNx), tungsten silicide (WSix), titanium (Ti), titanium nitride (TiNx), titanium silicon nitride (TiSiN), titanium aluminum nitride (TiAlN), tantalum (Ta), tantalum nitride (TaN), tantalum silicon nitride (TaSiN), tantalum aluminum nitride (TaAlN), carbon (C), silicon carbide (SiC), silicon carbon nitride (SiCN), copper (Cu), zinc (Zn), nickel (Ni), cobalt (Co), lead (Pd), platinum (Pt), molybdenum (Mo), ruthenium (Ru), and the like, and may include a combination thereof. The first electrode 44 and the second electrode 46 may include the same material or may include different materials. As an embodiment, the first electrode 44 and the second electrode 46 may be carbon electrodes.

Referring to FIG. 4B, the semiconductor device may include the first access line L1, the second access line L2, and the memory cell MC. The memory cell MC may be connected between the first access line L1 and the second access line L2. The memory cell MC may include the first electrode 44, the variable resistance layer 45, the second electrode 46, the sealing layer 47, and the nanostructure N.

The sealing layer 47 may be positioned between the variable resistance layer 45 and the second electrode 46, and the nanostructure N may be positioned therein. The sealing layer 47 may surround the nanostructure N and fill between the second electrode 46 and the variable resistance layer 45 and between the nanostructure N and the variable resistance layer 45. The nanostructure N and the variable resistance layer 45 may be separated by the sealing layer 47. In other words, the nanostructure N may be embedded in the sealing layer 47 such that the nanostructure N contacts the second electrode 46 and is spaced apart from the variable resistance layer 45.

According to the structure described above, the sealing layer 47 may be positioned in a first region between the first electrode 44 and the variable resistance layer 45, or in a second regions between the second electrode 46 and the variable resistance layer 45. In some embodiments, the sealing layer 47 in FIG. 4A and the sealing layer 47 in FIG. 4B may be positioned in the first region and the second region, respectively. A material movement between the first electrode 44, the variable resistance layer 45, and the second electrode 46 may be reduced through the sealing layer 47, and reliability may be improved.

The nanostructure N may be positioned inside the sealing layer 47, and the nanostructure N may be in contact with at least one of the first electrode 44 and the second electrode 46. Due to the nanostructure N, the memory cell MC may have an asymmetric electrode structure, the program window may be increased, and the program speed may be increased.

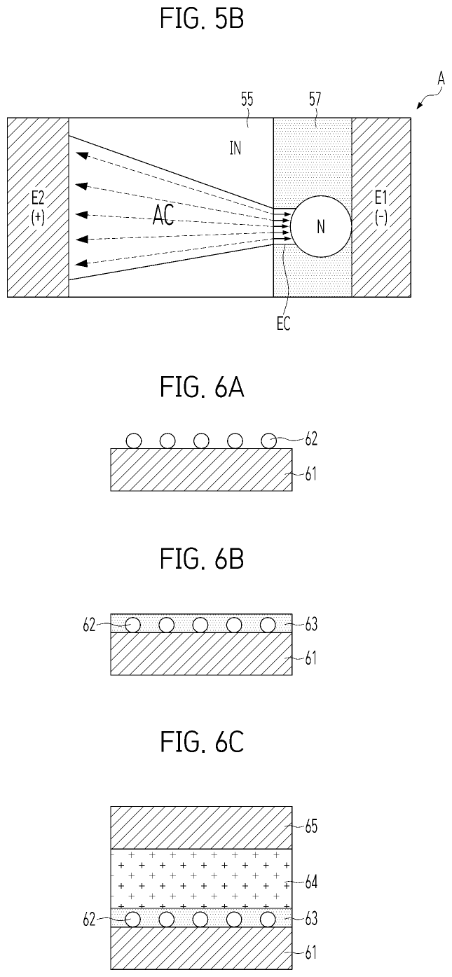

FIGS. 5A and 5B are diagrams illustrating an operation of a semiconductor device according to an embodiment of the present disclosure. FIG. 5B is an enlarged view of a portion A of FIG. 5A. Hereinafter, contents overlapping those described above may be omitted for the interest of brevity.

Referring to FIG. 5A, the semiconductor device may include at least one of a first electrode E1, a second electrode E2, a variable resistance layer 55, a sealing layer 57, and the nanostructure N. During a program operation, a bias of different polarities may be applied to the first electrode E1 and the second electrode E2 through the first access line L1 and the second access line L2. As an embodiment, during a reset operation, a negative (−) bias may be applied to the first electrode E1 and a positive (+) bias may be applied to the second electrode E2. As an embodiment, during the set operation, the positive (+) bias may be applied to the first electrode E1 and the negative (−) bias may be applied to the second electrode E2.

Referring to FIG. 5B, due to the nanostructure N, the first electrode E1 may have an effective area less than that of the second electrode E2. As an embodiment, after manufacturing the semiconductor device, a firing voltage for activating the memory cell MC may be applied to the first electrode E1 and the second electrode E2. Due to the firing voltage, a break-down of a sealing material between the nanostructure N and the variable resistance layer 55 may be caused, and an effective current path EC of a filament form may be formed in the sealing layer 57. Accordingly, an effective area of the first electrode E1 having a size of several nanometers corresponding to an area of the nanostructure N may be formed. As the effective area of the first electrode E1 is reduced by the nanostructure N, the memory cell MC may have an asymmetric electrode structure. For example, when the nanostructure N and the first electrode E1 function together as a single integrated electrode, the effective current path EC may be formed on an area of the nanostructure N and this area of the nanostructure N may function as a first effective area of the single integrated electrode. The first effective area of the single integrated electrode may be smaller than a second effective area of the second electrode E2 on which an active area AC of the variable resistance layer 55 is formed. As a result, a concentrated large electric field may be formed on the first effective area of the single integrated electrode to assist ionic migration of one or more elements in the variable resistance layer 55, thereby increasing a speed of a program operation.

As the memory cell MC has the asymmetric electrode structure, the variable resistance layer 55 may include an active region AC and an inactive region IN. During the program operation, a movement of an element may be caused in the active region AC, and the element might not move or a relatively small amount of element may move in the inactive region IN. As an embodiment, a selenium ion may move in the active region AC. As an electric field is concentrated on the nanostructure N of a small area, a movement of the selenium ion may be accelerated and the program speed may be increased. During the reset operation, the selenium ion may rapidly increase around the nanostructure N. Ion crowding may increase a composition change of the variable resistance layer 55 and increase a threshold voltage difference between a set state and a reset state. Therefore, the memory window may be increased.

FIGS. 6A to 6C are cross-sectional views illustrating a method of manufacturing a semiconductor device according to an embodiment of the present disclosure. Hereinafter, contents overlapping the contents described above may be omitted for the interest of brevity.

Referring to FIG. 6A, a first electrode 61 may be formed. Subsequently, a nanostructure 62 may be formed on the first electrode 61. The nanostructure 62 may be positioned on a surface of the first electrode 61 and may be electrically connected to the first electrode 61. As an embodiment, the nanostructure 62 may be formed by an island growth method using sputtering, atomic layer deposition ALD, or the like. The nanostructure 62 may include a structure having a size of several nanometers (nm), such as a nanodot, a nano rod, a nano wire, a nano tube, or a nano sheet. The nanostructure 62 may include a conductive material. As an embodiment, the nanostructure 62 may include at least one of nickel (Ni), silver (Ag), platinum (Pt), gold (Au), copper (Cu), and aluminum (Al).

Referring to FIG. 6B, a sealing layer 63 may be formed. The sealing layer 63 may be formed on the first electrode 61 to surround the nanostructure 62. As an embodiment, the sealing layer 63 may be formed to fill a space between the nanodots and surround each of the nanodots. The nanostructure 62 may be positioned inside the sealing layer 63 and substantially completely covered by the sealing layer 63. The sealing layer 63 may include a non-conductive material. As an embodiment, the sealing layer 63 may include at least one of oxide, nitride, and carbon. The sealing layer 63 may include a material having a relatively low thermal conductivity. The sealing layer 63 may include a material having a thermal conductivity less than 20 W/mK. As an embodiment, the sealing layer 63 may include at least one of FexOy, SiOx, TiOx, BNx, graphene, and SiNx. The sealing layer 63 may be a diffusion barrier layer.

Referring to FIG. 6C, a variable resistance layer 64 may be formed on the sealing layer 63. The variable resistance layer 64 may include at least one of a transition metal oxide, a perovskite-based material, an MTJ structure, and a chalcogenide material. The variable resistance layer 64 may change a phase or maintain the phase before or after the program operation. As an embodiment, the variable resistance layer 64 may maintain an amorphous state before and after the program operation. Subsequently, a second electrode 65 may be formed on the variable resistance layer 64.

Subsequently, after manufacturing the semiconductor device has been completed, a firing voltage may be applied to the first electrode 61 and the second electrode 65. Accordingly, an effective area of the first electrode 61 may be reduced, and a memory cell having an asymmetric electrode structure may be formed.

According to the manufacturing method described above, the nanostructure 62 may be formed on the surface of the first electrode 61, and the nanostructure 62 may be sealed with the sealing layer 63. Therefore, a memory cell including the first electrode 61 and the second electrode 65 having different effective areas may be formed.

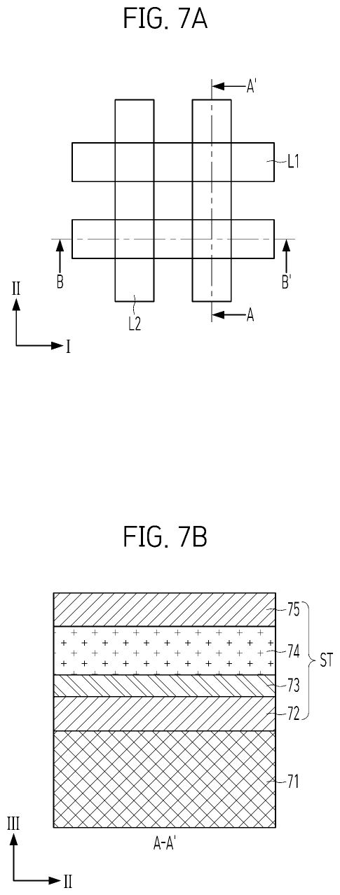

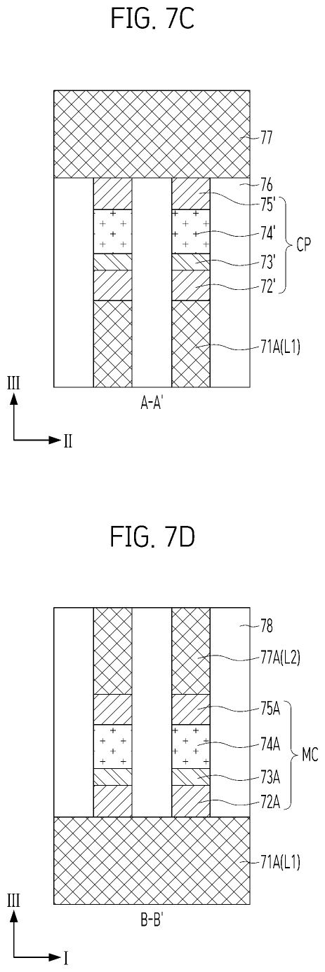

FIGS. 7A to 7D are diagrams illustrating a method of manufacturing a semiconductor device according to an embodiment of the present disclosure. FIG. 7A may be a plan view, FIGS. 7B and 7C may be cross-sectional views taken along a line A-A′ of FIG. 7A, and FIG. 7D may be a cross-sectional view taken along a line B-B′ of FIG. 7A. Hereinafter, contents overlapping the contents described above may be omitted for the interest of brevity.

Referring to FIG. 7B, a first conductive layer 71 may be formed. The first conductive layer 71 may be suitable for forming a first access line L1 and may include a metal such as tungsten.

Subsequently, a stack structure (or a stack) ST may be formed on the first conductive layer 71. The stack ST may include at least one of a first electrode layer 72, a sealing layer (or an initial sealing layer) 73, a variable resistance layer (or an initial variable resistance layer) 74, and a second electrode layer 75. A stack order of the layers included in the stack ST may be changed.

The sealing layer 73 may be positioned in a first region between the first electrode layer 72 and the variable resistance layer 74, or may be positioned in a second region between the variable resistance layer 74 and the second electrode layer 75. In some embodiments, the sealing layer 73 and an additional sealing layer (not shown) having a similar configuration to the sealing layer 73 and including the same materials as the sealing layer 73 may be positioned in the first region and the second region, respectively. A nanostructure may be positioned inside the sealing layer 73. As an embodiment, the nanostructure may be positioned on a surface of the first electrode layer 72 and may be electrically connected to the first electrode layer 72. The sealing layer 73 may include a non-conductive material. As an embodiment, the sealing layer 73 may include at least one of oxide, nitride, and carbon. The sealing layer 73 may include a material having a relatively low thermal conductivity. The sealing layer 73 may include a material having a thermal conductivity less than 20 W/mK. As an embodiment, the sealing layer 73 may include at least one of FexOy, SiOx, TiOx, BNx, graphene, and SiNx. The sealing layer 73 may be a diffusion barrier layer reducing a material movement between the first electrode layer 72, the variable resistance layer 74, and the second electrode layer 75.

Referring to FIG. 7C, first access lines 71A and cell patterns CP may be formed. As an embodiment, the cell patterns CP may be formed by etching the stack ST using a mask pattern as an etch barrier. Each of the cell patterns CP may include a first electrode layer 72′, a sealing layer 73′, a variable resistance layer 74′, and a second electrode layer 75′. The first conductive layer 71 may be etched to form the first access lines 71A. The first access lines 71A and the cell patterns CP may extend in the first direction I. Subsequently, first insulating layers 76 may be formed between the cell patterns CP and between the first access lines 71A.

Subsequently, a second conductive layer 77 may be formed on the cell patterns CP and the first insulating layers 76. The second conductive layer 77 may be suitable for forming the second access line L2 and may include a metal such as tungsten.

Referring to FIG. 7D, the second conductive layer 77 may be etched to form second access lines 77A extending in the second direction II crossing the first direction I. Subsequently, the cell patterns CP and the first insulating layers 76 may be etched to form the memory cells MC. Each of the memory cells MC may include a first electrode 72A, a sealing layer 73A, a variable resistance layer 74A, and a second electrode 75A. The memory cells MC may be positioned in cross regions of the first access lines 71A and the second access lines 77A, respectively. Subsequently, second insulating layers 78 may be formed between the memory cells MC and between the second access lines 77A.

According to the manufacturing method described above, the memory cell MC having the asymmetric electrode structure by the nanostructure may be formed. Therefore, the program window may be increased and the program speed may be increased.

Although embodiments according to the technical spirit of the present disclosure have been described with reference to the accompanying drawings, this is only for describing some embodiments according to the concept of the present disclosure, and embodiments of the present disclosure are not limited to the above-described embodiments. Within the scope of the technical spirit of the present disclosure, various forms of substitution, modification, and change of the embodiments may be possible.

What is claimed is:

1. A semiconductor device comprising:
a first electrode;
a second electrode;
a variable resistance layer positioned between the first electrode and the second electrode and maintaining a phase before and after a program operation;
a non-conductive sealing layer positioned between the first electrode and the variable resistance layer; and
a nanostructure positioned inside the non-conductive sealing layer and spaced apart from the variable resistance layer.

2. The semiconductor device of claim 1, wherein the nanostructure is electrically connected to the first electrode.

3. The semiconductor device of claim 1, wherein the nanostructure includes nanodots contacting the first electrode.

4. The semiconductor device of claim 1, wherein the nanostructure includes at least one of nickel (Ni), silver (Ag), platinum (Pt), gold (Au), copper (Cu), and aluminum (AI).

5. The semiconductor device of claim 1, wherein the nanostructure has an electrical conductivity sufficient to function as a single integrated electrode together with the first electrode.

6. The semiconductor device of claim 5, wherein the single integrated electrode has an effective area less than that of the second electrode.

7. The semiconductor device of claim 1, wherein the non-conductive sealing layer is a diffusion barrier between the first electrode, the variable resistance layer, and the second electrode.

8. The semiconductor device of claim 1, wherein the non-conductive sealing layer has a thermal conductivity less than 20 W/mk.

9. The semiconductor device of claim 1, wherein the non-conductive sealing layer includes at least one of FexOy, SiOx, TiOx, BNx, graphene, and SiNx.

10. The semiconductor device of claim 1, wherein the variable resistance layer includes a chalcogenide material.

11. A semiconductor device comprising:
a first electrode;
a second electrode;
a variable resistance layer positioned between the first electrode and the second electrode and maintaining a phase before and after a program operation;
a nanodot positioned on a surface of the first electrode; and
a non-conductive sealing layer surrounding the nanodot and filling between the first electrode and the variable resistance layer and between the nanodot and the variable resistance layer.

12. The semiconductor device of claim 11, wherein the nanodot is electrically connected to the first electrode, and has an electrical conductivity sufficient to function as a single integrated electrode together with the first electrode.

13. The semiconductor device of claim 11, wherein the nanodot includes at least one of nickel (Ni), silver (Ag), platinum (Pt), gold (Au), copper (Cu), and aluminum (AI).

14. The semiconductor device of claim 11, wherein the non-conductive sealing layer has a thermal conductivity less than 20 W/mk.

15. The semiconductor device of claim 11, wherein the non-conductive sealing layer includes at least one of FexOy, SiOx, TiOx, BNx, graphene, and SiNx.

16. The semiconductor device of claim 11, wherein the variable resistance layer includes a chalcogenide material.

17. A method of manufacturing a semiconductor device, the method comprising:
forming a first electrode;
forming a nanostructure on the first electrode;
forming a non-conductive sealing layer on the first electrode to surround the nanostructure;
forming a variable resistance layer on the non-conductive sealing layer; and
forming a second electrode on the variable resistance layer.

18. The method of claim 17, wherein forming the nanostructure comprises forming a nanodot on a surface of the first electrode.

19. The method of claim 17, wherein the nanodot includes at least one of nickel (Ni), silver (Ag), platinum (Pt), gold (Au), copper (Cu), and aluminum (AI).

20. The method of claim 17, wherein the non-conductive sealing layer has a thermal conductivity less than 20 W/mk.

21. The method of claim 17, wherein the non-conductive sealing layer includes at least one of FexOy, SiOx, TiOx, BNx, graphene, and SiNx.

22. The method of claim 17, wherein the variable resistance layer includes a chalcogenide material that maintains a phase before and after a program operation.

23. The method of claim 17, further comprising:
applying a firing voltage to the first electrode and the second electrode.
